(19) United States
(12) Patent Application Publication
(10) Pub. No.: US 2021/0297057 A1
(43) Pub. Date: Sep. 23, 2021

(54) METHOD FOR MANUFACTURING ELECTRONIC COMPONENT MODULE AND ELECTRONIC COMPONENT MODULE

(71) Applicant: Murata Manufacturing Co., Ltd., Nagaokakyo-shi (JP)

(72) Inventor: Takashi IWAMOTO, Nagaokakyo-shi (JP)

(21) Appl. No.: 17/342,677

(22) Filed: Jun. 9, 2021

Related U.S. Application Data
(63) Continuation of application No. PCT/JP2019/048711, filed on Dec. 12, 2019.

(30) Foreign Application Priority Data
Dec. 21, 2018 (JP) 2018-239971

(51) Int. Cl. H03H 9/10; H01L 41/047; H03H 3/007

(52) U.S. Cl. CPC H03H 9/1064; H03H 3/007; H01L 41/0472

(57) ABSTRACT

A method for manufacturing an electronic component module includes a support member preparation step, an electrode forming step, a component arrangement step, and a resin molding step. In the electrode forming step, a columnar electrode is formed on a conductive layer of a support member. In the component arrangement step, an electronic component is arranged on the support member. In the resin molding step, a resin structure that covers an outer peripheral surface of the columnar electrode and at least a portion of an outer peripheral surface of the electronic component is molded on the conductive layer. In the electrode forming step, the columnar electrode and the conductive layer are made of different materials. The method further includes a heat treatment step of heating the conductive layer and the columnar electrode so that mutual diffusion occurs between the conductive layer and the columnar electrode.

### CROSS REFERENCE TO RELATED APPLICATIONS

This application claims the benefit of priority to Japanese Patent Application No. 2018-239971 filed on Dec. 21, 2018 and is a Continuation Application of PCT Application No. PCT/JP2019/048711 filed on Dec. 12, 2019. The entire contents of each application are hereby incorporated herein by reference.

### BACKGROUND OF THE INVENTION

### 1. Field of the Invention

The present invention relates to a method for manufacturing an electronic component module and an electronic component module, and more particularly, to a method for manufacturing an electronic component module including an electronic component, a resin structure, and a columnar electrode, and to an electronic component module.

### 2. Description of the Related Art

As an example of a method for manufacturing an electronic component module, an existing method for manufacturing an electronic component built-in substrate incorporating an electronic component has been known (for example, see International Publication No. 2018/116799).

The electronic component built-in substrate is a substrate in which the electronic component is incorporated inside a resin structure. Here, the electronic component built-in substrate includes the resin structure, the electronic component, a through-electrode (columnar electrode), and a first wiring (conductor wiring portion).

The method for manufacturing the electronic component built-in substrate described in International Publication No. 2018/116799 includes a power feeding layer forming step, an electrode forming step, an electronic component arrangement step, and a sealing step. In the power feeding layer forming step, a power feeding layer (conductive layer) is formed on a base. In the electrode forming step, an electrode (columnar electrode) having a predetermined pattern connected to the power feeding layer is formed on the power feeding layer by an electrolytic plating method. In the electronic component arrangement step, the electronic component is arranged above a surface on which the electrode is formed in the power feeding layer. In the sealing step, the electronic component is sealed on the power feeding layer. Here, in the sealing step, a resin structure material that configures the resin structure so as to embed the electronic component and the electrode is arranged, and the resin structure material is cured by applying heat. As a result, the resin structure in which the electronic component and the electrode are incorporated (sealed) is formed.

In the above-described method for manufacturing the electronic component built-in substrate, the base is peeled off after the sealing step.

International Publication No. 2018/116799 describes that in a case where copper foil is used as the power feeding layer, the through-electrode may be formed by electrolytic plating using copper, thereby causing recrystallization at an interface between the power feeding layer and the through-electrode in a subsequent heat application step.

However, in the method for manufacturing the electronic component built-in substrate described in International Publication No. 2018/116799, in the sealing step, the electrode (columnar electrode) and the power feeding layer (conductive layer) are applied with force due to a flow of resin when the resin structure material of the resin structure is arranged, and contraction of the resin when the resin structure material is cured, and thus there is a problem that the electrode may be peeled off from the power feeding layer. In a case where the electrode is peeled off from the power feeding layer, there is a problem that positional accuracy of the electrode in the electronic component built-in substrate may be reduced.

### SUMMARY OF THE INVENTION

Preferred embodiments of the present invention provide methods for manufacturing, in electronic component modules each including a columnar electrode, an electronic component, and a resin structure, the electronic component modules are able to improve positional accuracy of the columnar electrode, and electronic component modules.

A method for manufacturing an electronic component module according to a preferred embodiment of the present invention includes a support member preparation step, an electrode forming step, a component arrangement step, and a resin molding step. In the support member preparation step, a support member including a support body with a first main surface and a second main surface and a conductive layer provided directly or indirectly on the first main surface of the support body is prepared. In the electrode forming step, a columnar electrode is formed on the conductive layer. In the component arrangement step, an electronic component is directly or indirectly arranged on the support member on a side of the first main surface of the support body. In the resin molding step, a resin structure that covers an outer peripheral surface of the columnar electrode and at least a portion of an outer peripheral surface of the electronic component is molded on the conductive layer. In the electrode forming step, the columnar electrode is formed of a material different from a material of the conductive layer. The method for manufacturing the electronic component module further includes a heat treatment step. In the heat treatment step, the conductive layer and the columnar electrode are heated so that mutual diffusion occurs between the conductive layer and the columnar electrode between the electrode forming step and the resin molding step.

An electronic component module according to a preferred embodiment of the present invention includes an electronic component, a resin structure, a columnar electrode, and a conductor wiring portion. The resin structure covers at least a portion of an outer peripheral surface of the electronic component. The columnar electrode passes through the resin structure. The conductor wiring portion is connected to the columnar electrode. The columnar electrode and the conductor wiring portion are made of different materials. Mutual diffusion occurs between the conductor wiring portion and the columnar electrode.

An electronic component module according to a preferred embodiment of the present invention includes an electronic component, a resin structure, a columnar electrode, and a conductor wiring portion. The resin structure covers at least a portion of an outer peripheral surface of the electronic component. The columnar electrode passes through the resin structure. The conductor wiring portion is connected to one end of the columnar electrode. The columnar electrode and the conductor wiring portion are made of different materials. The one end of the columnar electrode includes a diffusion region including a material different from a material of the columnar electrode.

In methods for manufacturing electronic component modules and electronic component modules according to preferred embodiments of the present invention, it is possible to improve the positional accuracy of the columnar electrodes in the electronic component modules including the columnar electrodes, the electronic components, and the resin structures.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view of an electronic component module according to Preferred Embodiment 1 of the present invention.

FIGS. 2A to 2D are process cross-sectional views for describing a method for manufacturing the above-described electronic component module.

FIGS. 3A to 3B are process plan views for describing the method for manufacturing the above-described electronic component module.

FIGS. 4A to 4E are process cross-sectional views for describing the method for manufacturing the above-described electronic component module.

FIGS. 5A to 5D are process cross-sectional views for describing the method for manufacturing the above-described electronic component module.

FIG. 6A is a cross-sectional view of an electronic component module according to Modification 1 of Preferred Embodiment 1 of the present invention. FIG. 6B is an explanatory view illustrating a main portion of the above-described electronic component module.

FIG. 7 is a process cross-sectional view for explaining a method for manufacturing the above-described electronic component module.

FIG. 8 is a process cross-sectional view for describing a method for manufacturing an electronic component module according to Modification 2 of Preferred Embodiment 1 of the present invention.

FIG. 9 is a cross-sectional view of an electronic component module according to Preferred Embodiment 2 of the present invention.

FIGS. 10A to 10D are process cross-sectional views for describing a method for manufacturing the above-described electronic component module.

FIG. 11 is a cross-sectional view of an electronic component module according to Modification 1 of Preferred Embodiment 2 of the present invention.

FIG. 12 is a cross-sectional view of an electronic component module according to Modification 2 of Preferred Embodiment 2 of the present invention.

FIG. 13 is an explanatory view of a main part of an example of the electronic component module according to Preferred Embodiment 1 of the present invention.

### DETAILED DESCRIPTION OF THE PREFERRED EMBODIMENTS

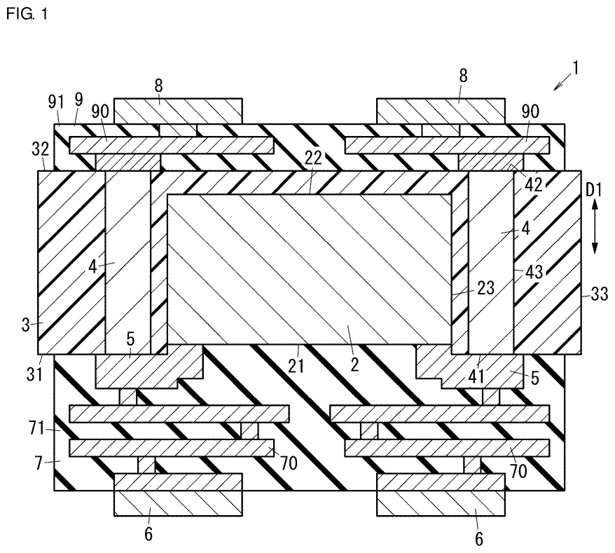

FIGS. 1, 2A to 2D, 3A to 3B, 4A to 4E, 5A to 5D, 6A to 6B, 7, 8, 9, 10A to 10D, 11, 12, and 13 are all schematic views, and ratios of sizes and thicknesses of respective elements in the drawings do not necessarily reflect actual dimensional ratios.

### Preferred Embodiment 1

### (1) Overall Configuration of Electronic Component Module

As illustrated in FIG. 1, an electronic component module 1 according to Preferred Embodiment 1 of the present invention includes a plurality of columnar electrodes 4, an electronic component 2, a resin structure 3, and a plurality of conductor wiring portions 5. The electronic component 2 is located on the side of the plurality of columnar electrodes 4. The resin structure 3 covers an outer peripheral surface 43 of each of the plurality of columnar electrodes 4 and at least a portion of an outer peripheral surface 23 (here, an entirety or substantially the entirety of the outer peripheral surface 23) of the electronic component 2. In the electronic component module 1, the resin structure 3 holds the electronic component 2 and the plurality of columnar electrodes 4. In the electronic component module 1, the resin structure 3 protects the electronic component 2 from an impact or the like from the outside. The plurality of columnar electrodes 4 pass through the resin structure 3 in a thickness direction D1 of the resin structure 3. The resin structure 3 includes a first main surface 31, a second main surface 32, and an outer peripheral surface 33.

Each of the plurality of conductor wiring portions 5 is connected to the corresponding columnar electrode 4 among the plurality of columnar electrodes 4. Each conductor wiring portion electrically connects the corresponding columnar electrode 4 among the plurality of columnar electrodes 4 and the electronic component 2.

In addition, the electronic component module 1 further includes a plurality of first terminal electrodes 6, a first wiring structure portion 7, a plurality of second terminal electrodes 8, and a second wiring structure portion 9.

Each of the plurality of first terminal electrodes 6 is a terminal electrode electrically connected to the corresponding conductor wiring portion 5 among the plurality of conductor wiring portions 5, and the like. Each of the plurality of first terminal electrodes 6 is, for example, an under bump metal (UBM). The first wiring structure portion 7 includes a plurality of wiring portions 70 corresponding to the plurality of first terminal electrodes 6.

Each of the plurality of first terminal electrodes 6 is electrically connected to the corresponding conductor wiring portion 5 among the plurality of conductor wiring portions 5, and the like via the corresponding wiring portion 70 among the plurality of wiring portions 70. Each of the plurality of wiring portions 70 electrically connects the corresponding conductor wiring portion 5 among the plurality of conductor wiring portions 5 and the electronic component 2.

Each of the plurality of second terminal electrodes 8 is electrically connected to the corresponding columnar electrode 4 among the plurality of columnar electrodes 4. Each of the plurality of second terminal electrodes 8 is, for example, an under bump metal (UBM). The second wiring structure portion 9 includes a plurality of wiring portions 90 corresponding to the plurality of second terminal electrodes 8. Each of the plurality of second terminal electrodes 8 is electrically connected to the corresponding columnar electrode 4 among the plurality of columnar electrodes 4 via the corresponding wiring portion 90 among the plurality of wiring portions 90.

The electronic component module 1 can be used, for example, as an interposer that is interposed between an electronic component different from the electronic component 2 and a circuit board. The circuit board is, for example, a printed wiring board.

### (2) Each Constituent Element of Electronic Component Module

Next, each element of the electronic component module 1 will be described with reference to the drawings.

### (2.1) Electronic Component

The electronic component 2 is, for example, a chip electronic component. The electronic component 2 includes a first main surface 21 and a second main surface 22 on opposite sides to each other in a thickness direction of the electronic component 2. The second main surface 22 faces the first main surface 21. In addition, the electronic component 2 includes the outer peripheral surface 23. An outer peripheral shape of the electronic component when viewed from the thickness direction of the electronic component 2 is a rectangular or substantially rectangular shape, but is not limited thereto, and may be a square or substantially square shape, for example.

The electronic component 2 is, for example, a semiconductor element (semiconductor chip). The semiconductor element may be, for example, an integrated circuit (IC), a micro processing unit (MPU), a power amplifier, a low noise amplifier, a radio frequency (RF) switch, or the like. The electronic component 2 is not limited to the semiconductor element, and may be, for example, an inductor, a capacitor, a resistor, or the like.

### (2.2) Resin Structure

As illustrated in FIG. 1, the resin structure 3 is a resin molded body configured to hold the electronic component 2. The resin structure 3 has a plate shape. The resin structure 3 includes the first main surface 31 and the second main surface 32 on opposite sides to each other in the thickness direction D1 thereof. The first main surface 31 and the second main surface 32 face each other. In addition, the resin structure 3 includes the outer peripheral surface 33. An outer peripheral shape of the resin structure 3 when viewed from the thickness direction D1 of the resin structure 3 is a rectangular or substantially rectangular shape, but is not limited thereto, and may be, for example, a square or substantially square shape. As viewed from the thickness direction D1 of the resin structure 3, the size of the resin structure 3 is larger than the size of the electronic component 2.

The resin structure 3 covers the outer peripheral surface 23 of the electronic component 2 and the second main surface 22 of the electronic component 2. That is, the electronic component 2 is inside the resin structure 3. The resin structure 3 holds the electronic component 2 in a state in which the first main surface 21 of the electronic component 2 is exposed.

The resin structure 3 is made of, for example, resin having an electrical insulation property, or the like. In addition, the resin structure 3 includes, for example, a filler mixed with the resin in addition to the resin, but the filler is not required. The resin is, for example, an epoxy resin. However, the resin is not limited to the epoxy resin, and may be, for example, a polyimide resin, an acrylic resin, a urethane resin, or a silicone resin. The filler is, for example, an inorganic filler such as silica, alumina, or the like. The resin structure 3 may include, for example, a black pigment such as carbon black, in addition to the resin and the filler.

### (2.3) Columnar Electrode

In the electronic component module 1, as illustrated in FIG. 1, the plurality of columnar electrodes 4 are arranged on the side of the electronic component 2. The plurality of columnar electrodes 4 are spaced apart from the outer peripheral surface 23 of the electronic component 2. The plurality of columnar electrodes 4 are spaced apart from one another. The plurality of columnar electrodes 4 are held by the resin structure 3. In the electronic component module 1, the position and the number of the columnar electrodes 4 are not particularly limited.

Each of the plurality of columnar electrodes 4 has, for example, a circular or substantially circular cylinder shape. Each of the plurality of columnar electrodes 4 includes a first end surface 41 and a second end surface 42 on opposite sides to each other in a direction parallel or substantially parallel to the thickness direction D1 of the resin structure 3. A portion of the corresponding conductor wiring portion 5 among the plurality of conductor wiring portions 5 overlaps each of the first end surfaces 41 of the plurality of columnar electrodes 4. In the electronic component module 1, each of the plurality of columnar electrodes 4 is electrically connected to the corresponding conductor wiring portion 5 among the plurality of conductor wiring portions 5.

A material of each columnar electrode 4 is, for example, a metal. In the electronic component module 1 according to Preferred Embodiment 1, the material of each columnar electrode 4 is, for example, copper.

### (2.4) Conductor Wiring Portion

The conductor wiring portion 5 electrically connects the columnar electrode 4 and the electronic component 2 on the side of the first main surface 31 of the resin structure 3 and on the side of the first main surface 21 of the electronic component 2. The conductor wiring portion 5 is disposed over the first end surface 41 of the columnar electrode 4 and the first main surface 21 (a surface of a terminal portion in the electronic component 2) of the electronic component 2. Note that the electronic component module 1 may include an insulating layer to improve a close contact property with the conductor wiring portion 5 between a portion of the conductor wiring portion 5 and the first main surface 31 of the resin structure 3 and the first main surface 21 of the electronic component 2.

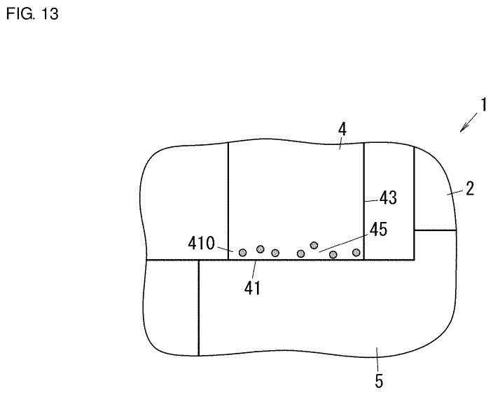

A material of the conductor wiring portion 5 is, for example, an alloy or a metal. In the electronic component module 1 according to Preferred Embodiment 1, the conductor wiring portion 5 and the columnar electrode 4 are made of different materials from each other. Here, the “different materials from one another” include a case where they have different elements, a case where the presence or absence of an additive is different, a case where all of the plurality of elements are the same or substantially the same and compositions are different, a case where the compositions are the same or substantially the same and the additives are different, and the like. The material of the conductor wiring portion 5 is, for example, a material obtained by adding at least one selected from the group consisting of chromium, nickel, iron, cobalt, and zinc to copper, or a copper alloy. Here, the copper alloy is an alloy containing copper and at least one selected from the group consisting of chromium, nickel, iron, cobalt, and zinc. The copper alloy is, for example, a copper-chromium alloy, a copper-nickel alloy, a copper-iron alloy, a copper-cobalt alloy, or a copper-zinc alloy. As illustrated in FIG. 13, the electronic component module 1 according to Preferred Embodiment 1 includes a diffusion region 45 made of a material different from the material of the columnar electrode 4 in one end 410 in the columnar electrode 4 on the conductor wiring portion 5 side. The diffusion region 45 will be described in the method for manufacturing the electronic component module 1 described later.

### (2.5) First Terminal Electrode

The plurality of first terminal electrodes 6 are located away from the first main surface 31 on the first main surface 31 side of the resin structure 3.

Each first terminal electrode 6 has, for example, a laminated structure including a nickel layer on the first wiring structure portion 7 and a gold layer on the nickel layer. Each first terminal electrode 6 is not limited to the laminated structure, and may have a single-layer structure.

### (2.6) First Wiring Structure Portion

The first wiring structure portion 7 is interposed between the plurality of first terminal electrodes 6 and the resin structure 3, the plurality of conductor wiring portions 5, and the electronic component 2. The first wiring structure portion 7 overlaps the first main surface 31 of the resin structure 3, the first main surface 21 of the electronic component 2, and the conductor wiring portion 5 in a plan view from the thickness direction D1 of the resin structure 3.

The first wiring structure portion 7 includes the plurality of wiring portions 70 corresponding to the plurality of first terminal electrodes 6, and an insulating portion 71 by which the plurality of wiring portions 70 are electrically insulated from one another. Each of the plurality of first terminal electrodes 6 is provided on the corresponding wiring portion 70 among the plurality of wiring portions 70, and is electrically connected to the corresponding conductor wiring portion 5 among the plurality of conductor wiring portions 5, and the like via the wiring portion 70.

The first wiring structure portion 7 has a multilayer wiring structure, and includes a plurality of wiring layers, a plurality of interlayer insulating films, and a surface insulating layer. The plurality of wiring layers are each patterned in a predetermined pattern. Each of the plurality of wiring portions 70 of the first wiring structure portion 7 includes a portion of each of the plurality of wiring layers. The insulating portion 71 of the first wiring structure portion 7 includes a plurality of interlayer insulating films and a surface insulating layer. A material of each wiring layer is, for example, copper, but is not limited thereto. A material of each interlayer insulating film is, for example, an organic material such as polyimide, for example, but is not limited thereto. Here, the material of each interlayer insulating film is not limited to an organic material such as polyimide, and may be an inorganic material, for example. A material of the surface insulating layer is a material having a lower solder wetting property than that of the first terminal electrode 6. The material of the surface insulating layer is, for example, an organic material such as polyimide, for example, but is not limited thereto. The material of the surface insulating layer is not limited to an organic material such as polyimide, and may be an inorganic material.

### (2.7) Second Terminal Electrode

The plurality of second terminal electrodes 8 is located away from the second main surface 32 on the second main surface 32 side of the resin structure 3. Each of the plurality of second terminal electrodes 8 is electrically connected to the corresponding columnar electrode 4 among the plurality of columnar electrodes 4 via the second wiring structure portion 9.

Each second terminal electrode 8 has, for example, a laminated structure of a nickel layer on the second wiring structure portion 9 and a gold layer on the nickel layer. Each second terminal electrode 8 is not limited to the laminated structure, and may have a single-layer structure.

### (2.8) Second Wiring Structure Portion

The second wiring structure portion 9 is interposed between the plurality of second terminal electrodes 8 and the resin structure 3 and the plurality of columnar electrodes 4. The second wiring structure portion 9 overlaps the second main surface 32 of the resin structure 3 and the second end surfaces 42 of the plurality of columnar electrodes 4 in a plan view from the thickness direction D1 of the resin structure 3.

The second wiring structure portion 9 includes the plurality of wiring portions 90 corresponding to the plurality of second terminal electrodes 8, and an insulating portion 91 by which the plurality of wiring portions 90 are electrically insulated from one another. Each of the plurality of second terminal electrodes 8 is provided on the corresponding wiring portion 90 among the plurality of wiring portions 90, and is electrically connected to the corresponding columnar electrode 4 among the plurality of columnar electrodes 4 via the wiring portion 90.

The second wiring structure portion 9 includes, for example, a plurality of wiring layers and a plurality of insulating films. Each of the plurality of wiring layers is patterned in a predetermined pattern, and includes a plurality of conductive portions. Each of the plurality of wiring portions 90 of the second wiring structure portion 9 includes a portion (one conductive portion among the plurality of conductive portions) of each of the plurality of wiring layers, but is not limited thereto. The insulating portion 91 of the second wiring structure portion 9 includes a plurality of insulating films. A material of each insulating film is, for example, an organic material such as polyimide, for example, but is not limited thereto. Here, the material of each insulating film is not limited to an organic material such as polyimide, and may be an inorganic material. The second wiring structure portion 9 may have a multilayer wiring structure.

### (3) Method for Manufacturing Electronic Component Module

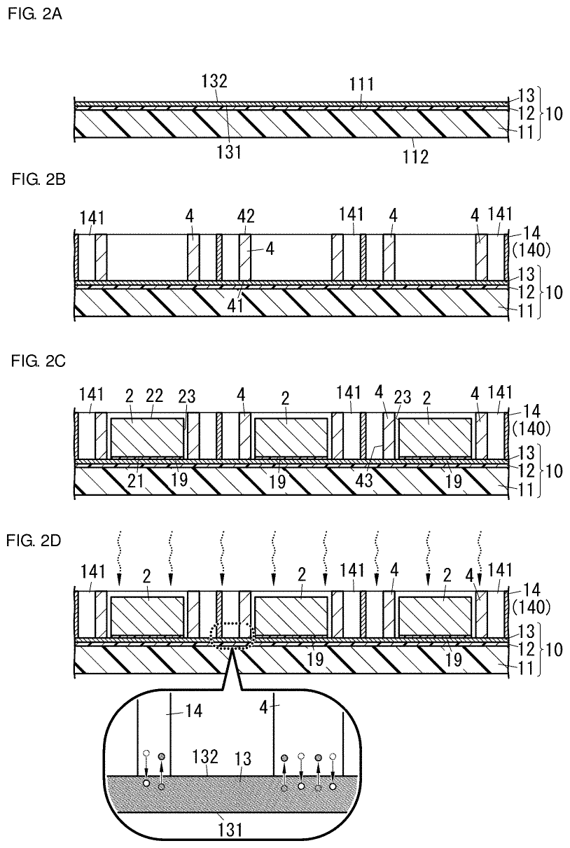

Next, a method for manufacturing the electronic component module 1 according to Preferred Embodiment 1 will be described with reference to FIGS. 2A to 2D, 3A to 3B, 4A to 4E, and 5A to 5D.

In the method for manufacturing the electronic component module 1, after the electronic component 2 is prepared, a first step to a thirteenth step are sequentially performed.

In the first step, as illustrated in FIG. 2A, a support member 10 is prepared. In the first step, a conductive layer 13 is provided on a first main surface 111 of a support body 11 including the first main surface 111 and a second main surface 112 via a bonding layer 12. That is, in the first step, the conductive layer 13 is indirectly provided on the first main surface 111 of the support body 11. The support member 10 includes the support body 11, the bonding layer 12, and the conductive layer 13. The support body 11 is made of, for example, a glass epoxy material. The bonding layer 12 is made of, for example, an acrylic-based adhesive material. The bonding layer 12 is provided directly on the first main surface 111 of the support body 11. The conductive layer 13 includes a first main surface 131 on the support body 11 side and a second main surface 132 on the opposite side of the first main surface 131. The first main surface 131 and the second main surface 132 of the conductive layer 13 face each other. In the method for manufacturing the electronic component module 1 according to Preferred Embodiment 1, a material of the conductive layer 13 is the same or substantially the same as that of the conductor wiring portion 5. The material of the conductive layer 13 is, for example, a material obtained by adding at least one selected from the group consisting of chromium, nickel, iron, cobalt, and zinc to copper, or a copper alloy. Here, the copper alloy includes copper and at least one selected from the group consisting of chromium, nickel, iron, cobalt, and zinc. The copper alloy is, for example, a copper-chromium alloy, a copper-nickel alloy, a copper-iron alloy, a copper-cobalt alloy, a copper-zinc alloy, or the like. The conductive layer 13 is made of, for example, copper foil or copper alloy foil obtained by adding at least one selected from the group consisting of chromium, nickel, iron, cobalt, and zinc to copper. As an example, the material of the conductive layer 13 is obtained by adding nickel to copper in a proportion of about 1% by weight. A thickness of the conductive layer 13 is, for example, about 20 μm. Note that the support body 11 is not limited to a glass epoxy material, and may be made of, for example, stainless steel, a PET film, a PEN film, or a polyimide film. In the method for manufacturing the electronic component module 1 according to Preferred Embodiment 1, the first step includes a support member preparation step of preparing the support member 10 including the support body 11 including the first main surface 111 and the second main surface 112, and the conductive layer 13 provided directly or indirectly on the first main surface 111 of the support body 11.

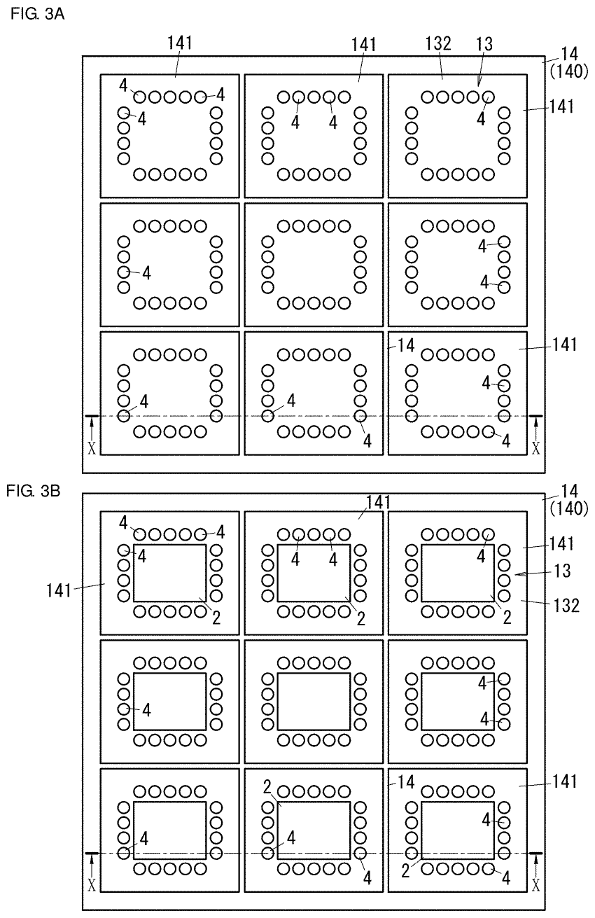

In the second step, as illustrated in FIGS. 2B and 3A, the columnar electrode 4 is formed on the conductive layer 13. The columnar electrode 4 has, for example, a circular or substantially circular cylinder shape. In addition, in the second step, as illustrated in FIGS. 2B and 3A, a conductor frame 14 is formed on the conductive layer 13. The conductor frame 14 includes a cavity 141 that defines a molding planned region of the resin structure 3 on the conductive layer 13. An opening shape of the cavity 141 has a rectangular or substantially rectangular shape corresponding to the outer peripheral shape of the resin structure 3. In the method for manufacturing the electronic component module 1 according to Preferred Embodiment 1, the second step includes an electrode forming step of forming the columnar electrode 4 on the conductive layer 13 and a conductor frame forming step of forming the conductor frame 14 including the cavity 141 that defines the molding planned region of the resin structure 3 on the conductive layer 13. Therefore, in the method for manufacturing the electronic component module 1 according to Preferred Embodiment 1, the electrode forming step and the conductor frame forming step are the same step.

In the conductor frame forming step, as illustrated in FIG. 3A, a lattice frame 140 including the plurality of cavities 141 (nine cavities in the illustrated example) is formed on the conductive layer 13, as the conductor frame 14. FIG. 2B is a cross-sectional view corresponding to a cross section taken along a line X-X in FIG. 3A. Further, in the electrode forming step, at least one (eighteen in the example of FIG. 3A) columnar electrode 4 is formed on the conductive layer 13 inside each of the plurality of cavities 141 of the lattice frame 140.

In the second step described above, first, a positive photoresist layer covering the second main surface 132 of the conductive layer 13 is formed. Then, portions in formation planned regions of each of the plurality of columnar electrodes 4 and the conductor frame 14 (lattice frame 140) in the photoresist layer are removed by using photolithography, so that portions that define and function as an underlying surface of each of the plurality of columnar electrodes 4 and the conductor frame 14 of the second main surface 132 of the conductive layer 13 are exposed. After that, a cleaning treatment of the second main surface 132 of the conductive layer 13 is performed by a plasma treatment. In the cleaning treatment, an organic substance and an oxide of the second main surface 132 are removed by the plasma treatment. After the cleaning treatment, the plurality of columnar electrodes 4 and the conductor frame 14 (lattice frame 140) are formed by electrolytic plating. When forming the plurality of columnar electrodes 4 and the conductor frame 14, an anode facing a surface of the photoresist layer through a plating solution containing copper sulfate and a cathode formed of the conductive layer 13 are energized, and the plurality of columnar electrodes 4 and the conductor frame 14 are deposited from the exposed portion of the second main surface 132 of the conductive layer 13 along a thickness direction of the photoresist layer. The plating solution includes, in addition to the copper sulfate, for example, a surfactant, a leveling agent, a plating brightener, an antifoaming agent, and the like. After electrolytic plating, the photoresist layer is removed.

In the third step, as illustrated in FIGS. 2C and 3B, the plurality of electronic components 2 are temporarily fixed on the conductive layer 13. More specifically, in the third step, a plurality of resin adhesive layers 19 for temporarily fixing the plurality of electronic components 2 are formed on the second main surface 132 of the conductive layer 13, and then the plurality of electronic components 2 are provided on the corresponding resin adhesive layer 19 among the plurality of resin adhesive layers 19. Here, in the third step, the plurality of electronic components 2 are temporarily fixed on the conductive layer 13 by causing the first main surfaces 21 of the plurality of electronic components 2 to face the resin adhesive layer 19 in one-to-one correspondence among the plurality of resin adhesive layers 19 to be provided on the resin adhesive layers 19. FIG. 2C is a cross-sectional view corresponding to a cross section taken along a line X-X in FIG. 3B. The resin adhesive layer 19 is formed of, for example, a positive resist having photosensitivity. Here, in the method for manufacturing the electronic component module 1 according to Preferred Embodiment 1, the third step includes a component arrangement step of arranging the electronic component 2 directly or indirectly on the support member 10 on the first main surface 111 side of the support body 11. In the component arrangement step, the electronic component 2 is indirectly provided on the second main surface 132 of the conductive layer 13 at a position spaced away from the outer peripheral surface 23 of each columnar electrode 4 located inside the cavity 141 of the conductor frame 14.

In the fourth step, as illustrated in FIG. 2D, the conductive layer 13 and each columnar electrode 4 are heated so that mutual diffusion occurs between the conductive layer 13 and each columnar electrode 4. In the method for manufacturing the electronic component module 1 according to Preferred Embodiment 1, the fourth step includes a heat treatment step of heating the conductive layer 13 and each columnar electrode 4 so that mutual diffusion occurs between the conductive layer 13 and each columnar electrode 4. In the heat treatment step, the conductive layer 13 and each columnar electrode 4 are heated at a heat treatment temperature at which mutual diffusion occurs between the conductive layer 13 and each columnar electrode 4. The heat treatment temperature may be appropriately determined in consideration of the material of each columnar electrode 4, the material of the conductive layer 13, a heat resistant temperature of the support body 11, a heat resistant temperature of the bonding layer 12, a heat resistant temperature of the electronic component 2, and the like. The heat treatment temperature is, for example, equal to or higher than about 100° C. and equal to or lower than about 200° C. In addition, in the fourth step, when the conductive layer 13 and each columnar electrode 4 are heated, the conductor frame 14 is also heated. Therefore, in the method for manufacturing the electronic component module 1 according to Preferred Embodiment 1, in the heat treatment step, the conductive layer 13 and the conductor frame 14 are heated so that mutual diffusion occurs between the conductive layer 13 and the conductor frame 14. For example, in a case where the material of each columnar electrode 4 is copper, and the material of the conductive layer 13 is a copper-nickel alloy, by performing the fourth step, nickel of the conductive layer 13 diffuses to the one end 410 of each columnar electrode 4, and the diffusion region 45 (see FIG. 13) is formed. In a partially enlarged portion of FIG. 2D, focusing on the conductive layer 13 and the columnar electrode 4, gray circles indicate nickel diffused from the conductive layer 13 to the columnar electrode 4, and white circles indicate copper diffused from the columnar electrode 4 to the conductive layer 13. In the partially enlarged portion of FIG. 2D, focusing on the conductive layer 13 and the conductor frame 14, the gray circles indicate nickel diffused from the conductive layer 13 to the conductor frame 14, and the white circles indicate copper diffused from the conductor frame 14 to the conductive layer 13.

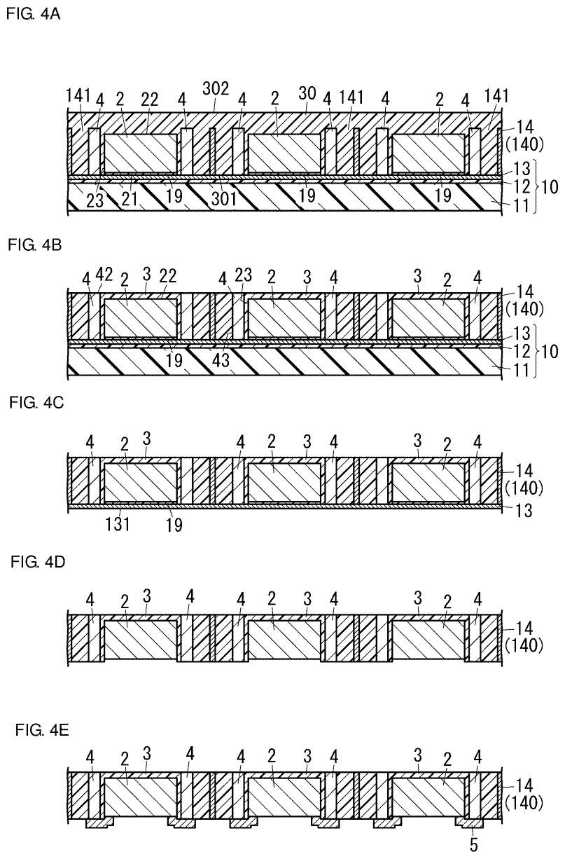

In the fifth step, as illustrated in FIG. 4A, a resin molded body 30 that defines and functions as a source of the plurality of resin structures 3 (see FIG. 1 and FIG. 4B) is molded on the conductive layer 13. Here, in the fifth step, the resin molded body 30 is molded, which covers the outer peripheral surface 43 and the second end surface 42 of each columnar electrode 4 on the conductive layer 13, each cavity 141 of the lattice frame 140 and an end surface in the lattice frame 140 on the side opposite to the conductive layer 13 side, and the outer peripheral surface 23 and the second main surface 22 of the electronic component 2. In the fifth step, when the resin molded body 30 is molded, in order to reduce or prevent generation of bubbles in each cavity 141 of the lattice frame 140, an uncured resin layer that defines and functions as a source of the resin molded body 30 is provided in a formation planned region of the resin molded body 30 in a vacuum atmosphere or in a reduced-pressure atmosphere. A material of the resin layer is, for example, an epoxy-based resin including an inorganic filler. In the fifth step, after the resin layer is provided, the resin layer is cured to obtain the resin molded body 30. The resin molded body 30 includes a first surface 301 and a second surface 302 on opposite sides to each other in a thickness direction thereof. The first surface 301 of the resin molded body 30 is a surface in contact with the second main surface 132 of the conductive layer 13. The second surface 302 of the resin molded body 30 is a surface facing the first surface 301. The resin molded body 30 is thicker than the resin structure 3. In the thickness direction of the resin molded body 30, a portion of the resin molded body 30 is interposed between the second surface 302 of the resin molded body 30 and each columnar electrode 4.

In the sixth step, as illustrated in FIG. 4B, the resin molded body 30 (see FIG. 4A) is polished from the second surface 302 side of the resin molded body 30 to the thickness of each resin structure 3, thus forming the plurality of resin structures 3. Here, in the sixth step, the resin molded body 30 is polished so that the second end surface 42 of each columnar electrode 4 is exposed and the second surface 302 of the resin molded body 30 is flush or substantially flush with the second end surface 42 of each columnar electrode 4. In the sixth step, the second end surface 42 of each columnar electrode 4 is exposed, and the second end surface 42 of each columnar electrode 4 and the second surface 302 of the resin molded body 30 are not necessarily flush or substantially flush with each other. By performing the sixth step, a structure including the plurality of resin structures 3, the plurality of columnar electrodes 4, and the conductor frame 14 (lattice frame 140) is formed. In the method for manufacturing the electronic component module 1 according to Preferred Embodiment 1, the fifth step and the sixth step are included in a resin molding step of molding the resin structure 3 that covers the outer peripheral surface 43 of the columnar electrode 4 and at least a portion of the outer peripheral surface 23 of the electronic component 2 on the conductive layer 13. In the resin molding step in the method for manufacturing the electronic component module 1 according to Preferred Embodiment 1, the resin structure 3 is molded so as to cover not only the outer peripheral surface 23 with respect to the electronic component 2 but also the second main surface 22 of the electronic component 2.

In the seventh step, the support body 11 and the bonding layer 12 are removed from a structure (see FIG. 4B) including the plurality of electronic components 2, the plurality of resin structures 3, the plurality of columnar electrodes 4, the conductor frame 14, the support body 11, the bonding layer 12, the conductive layer 13, and the plurality of resin adhesive layers 19 to obtain a structure illustrated in FIG. 4C. Accordingly, in the seventh step, the first main surface 131 of the conductive layer 13 is exposed. In the seventh step, for example, the adhesive strength of the bonding layer 12 is reduced, and the support body 11 is removed (peeled off). The bonding layer 12 is made of, for example, an adhesive capable of reducing the adhesive strength by ultraviolet rays.

In the eighth step, the conductive layer 13 is removed from the structure (see FIG. 4C) including the plurality of electronic components 2, the plurality of resin structures 3, the plurality of columnar electrodes 4, the conductor frame 14, the conductive layer 13, and the plurality of resin adhesive layers 19, and further, the adhesive layer 19 is removed to obtain a structure illustrated in FIG. 4D. In the eighth step, for example, the conductive layer 13 is removed by etching. Further, in the eighth step, the resin adhesive layer 19 is removed by, for example, exposing and then developing the resin adhesive layer 19.

In the ninth step, as illustrated in FIG. 4E, the conductor wiring portion 5 is formed on the structure illustrated in FIG. 4D. Here, in the ninth step, the conductor wiring portion is formed by, for example, sputtering, a photolithography technique, an etching technique, and a plating technique.

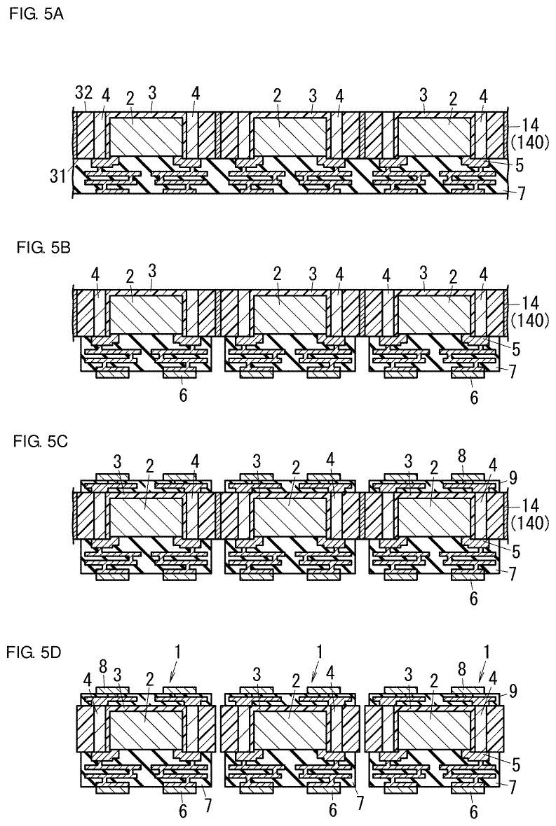

In the tenth step, as illustrated in FIG. 5A, the first wiring structure portion 7 is formed. In the tenth step, for example, each wiring layer of the first wiring structure portion is formed by sputtering, the photolithography technique, the etching technique, and a plating technique. Further, in the tenth step, each interlayer insulating film and the surface insulating layer of the first wiring structure portion 7 are formed by, for example, a coating technique, such as spin coating, and a photolithography technique. Note that when forming each interlayer insulating film, a curing temperature at the time of curing the applied uncured resin is, for example, equal to or higher than about 180° C. The material of each wiring layer formed in the tenth step is preferably the same as that of the conductor frame 14, from the viewpoint of making a linear expansion coefficient of the wiring layer be the same or substantially the same as that of the conductor frame 14.

In the eleventh step, as illustrated in FIG. 5B, the plurality of first terminal electrodes 6 is formed. Here, in the eleventh step, the plurality of first terminal electrodes 6 are formed by, for example, sputtering, a photolithography technique, an etching technique, and a plating technique.

In the twelfth step, as illustrated in FIG. 5C, the second wiring structure portion 9 is formed, and thereafter, the plurality of second terminal electrodes 8 are formed. Here, in the twelfth step, for example, each insulating film of the second wiring structure portion 9 is formed by a coating technique, such as spin coating, and a photolithography technique. When forming each insulating film, the curing temperature at the time of curing the applied uncured resin is, for example, equal to or higher than about 180° C. Further, in the twelfth step, for example, each wiring layer of the second wiring structure portion 9 is formed by sputtering, a photolithography technique, and a plating technique. In addition, in the twelfth step, for example, the plurality of second terminal electrodes 8 are formed by sputtering, plating, a photolithography technique, and an etching technique. The material of each wiring layer formed in the twelfth step is preferably the same as that of the conductor frame 14, from the viewpoint of making the linear expansion coefficient of the wiring layer be the same or substantially the same as that of the conductor frame 14.

In the method for manufacturing the electronic component module 1 according to Preferred Embodiment 1, the support body 11 having a size capable of forming an assembly of the plurality of electronic component modules 1 as the support body 11 is used in the first step, and by performing the first step to the twelfth step, it is possible to form the structure that defines and functions as a source of the plurality of electronic component modules 1.

In the thirteenth step, as illustrated in FIG. 5D, the conductor frame 14 (lattice frame 140) is removed, thus separating the structure (see FIG. 5C) that defines and functions as the source of the plurality of electronic component modules 1 into the individual electronic component modules 1. Accordingly, in the thirteenth step, the plurality of electronic component modules 1 are obtained. Here, in the thirteenth step, the conductor frame 14 is removed by etching the conductor frame 14. In the thirteenth step, the conductor frame 14 is removed by, for example, wet etching. As an etchant for wet etching the conductor frame 14, for example, a nitric acid-based solution, an iron chloride-based solution, a sulfuric acid-based solution, or the like can be used. For the etchant used to remove the conductor frame 14 in the thirteenth step, from the viewpoint of selectively etching the conductor frame 14 with respect to the resin structure 3, an etchant having large etching selectivity (an etching rate of the conductor frame 14/an etching rate of the resin structure 3) is preferable, and an etchant in which the resin structure 3 is not etched is more preferable. In the method for manufacturing the electronic component module 1 according to Preferred Embodiment 1, the twelfth step includes a conductor frame removing step of removing the conductor frame 14 by etching the conductor frame 14 after the resin molding step.

### Advantageous Effects

The method for manufacturing the electronic component module 1 according to Preferred Embodiment 1 includes the support member preparation step, the electrode forming step, the component arrangement step, and the resin molding step. In the support member preparation step, the support member 10 including the support body 11 and the conductive layer 13 is prepared. The support body 11 includes the first main surface 111 and the second main surface 112. The conductive layer 13 is indirectly provided on the first main surface 111 of the support body 11 via the bonding layer 12. In the electrode forming step, the columnar electrode 4 is formed on the conductive layer 13. In the component arrangement step, the electronic component 2 is indirectly arranged on the support member 10 on the first main surface 111 side of the support body 11 (here, the electronic component 2 is arranged on the support member 10 via the resin adhesive layer 19). In the resin molding step, the resin structure 3 that covers the outer peripheral surface 43 of the columnar electrode 4 and at least a portion of the outer peripheral surface 23 of the electronic component 2 (here, the entirety or substantially the entirety of the outer peripheral surface 23) is molded on the conductive layer 13. In the electrode forming step, the columnar electrode 4 is made of a material different from that of the material of the conductive layer 13. The method for manufacturing the electronic component module 1 further includes the heat treatment step. In the heat treatment step, between the electrode forming step and the resin molding step, the conductive layer 13 and the columnar electrode 4 are heated so that mutual diffusion occurs between the conductive layer 13 and the columnar electrode 4. Note that, in the method for manufacturing the electronic component module 1 according to Preferred Embodiment 1, the resin structure 3 is molded so as to cover the second main surface 22 of the electronic component 2, in addition to the outer peripheral surface 43 of the columnar electrode 4 and the entirety or substantially the entirety of the outer peripheral surface 23 of the electronic component 2 in the resin molding step.

In the method for manufacturing the electronic component module 1 according to Preferred Embodiment 1, positional accuracy of the columnar electrode 4 can be improved in the electronic component module 1 including the columnar electrode 4, the electronic component 2, and the resin structure 3. This point will be further described. In the method for manufacturing the electronic component module according to Preferred Embodiment 1, before the resin molding step, the conductive layer 13 and the columnar electrode 4 are heated so that mutual diffusion occurs between the conductive layer 13 and the columnar electrode 4 in the heat treatment step, and thus it is possible to increase bonding strength between the conductive layer 13 and the columnar electrode 4. Accordingly, in the method for manufacturing the electronic component module 1 according to Preferred Embodiment 1, when the resin structure 3 is formed in the resin molding step, in a case where the conductive layer 13 and the columnar electrode 4 are applied with force due to the flow of resin and the contraction of resin when the resin is cured, the columnar electrode 4 is less likely to be peeled off from the conductive layer 13. Therefore, it is possible to improve the positional accuracy of the columnar electrode 4 in the electronic component module 1 including the columnar electrode 4, the electronic component 2, and the resin structure 3.

Further, in the electrode forming step of the method for manufacturing the electronic component module 1 according to Preferred Embodiment 1, the columnar electrode 4 is formed by electrolytic plating, for example. As a result, in the method for manufacturing the electronic component module 1 according to Preferred Embodiment 1, it is possible to easily form the columnar electrode 4.

Further, the method for manufacturing the electronic component module 1 according to Preferred Embodiment 1 includes the conductor frame forming step of forming the conductor frame 14 including the cavity 141 that defines the molding planned region of the resin structure 3 on the conductive layer 13 before the resin molding step. Here, in the method for manufacturing the electronic component module 1 according to Preferred Embodiment 1, the conductive layer 13 and the conductor frame 14 are heated in the heat treatment step. Therefore, in the heat treatment step, the conductive layer 13 and the conductor frame 14 are heated so that mutual diffusion occurs between the conductive layer 13 and the conductor frame 14, and thus it is possible to increase the bonding strength between the conductive layer 13 and the conductor frame 14. Accordingly, in the method for manufacturing the electronic component module 1 according to Preferred Embodiment 1, when the resin structure 3 is formed in the resin molding step, in a case where the columnar electrode 4 and the conductive layer 13 are applied with the force due to the flow of the resin and the contraction of the resin when the resin is cured, the columnar electrode 4 is less likely to be peeled off from the conductive layer 13. Therefore, relative positional accuracy between the electronic component 2 and the columnar electrode 4 can be improved in the electronic component module 1 including the columnar electrode 4, the electronic component 2, and the resin structure 3.

Further, in the method for manufacturing the electronic component module 1 according to Preferred Embodiment 1, the electrode forming step and the conductor frame forming step are the same step. Accordingly, in the method for manufacturing the electronic component module 1 according to Preferred Embodiment 1, the columnar electrode 4 and the conductor frame 14 can be formed by the same step, and the relative positional accuracy between the columnar electrode 4 and the conductor frame 14 can be improved.

Further, in the method for manufacturing the electronic component module 1 according to Preferred Embodiment 1, in the conductor frame forming step, the lattice frame 140 including the plurality of cavities 141 is formed on the conductive layer 13 as the conductor frame 14. In the electrode forming step, the plurality of columnar electrodes 4 are formed with respect to the conductive layer 13. In the electrode forming step, when the plurality of columnar electrodes 4 is formed, at least one columnar electrode 4 (18 columnar electrodes in the example of FIG. 3A) is formed on the conductive layer 13 inside each of the plurality of cavities 141 of the lattice frame 140. In the component arrangement step, the plurality of electronic components 2 are arranged on the support member 10. In the component arrangement step, when the plurality of electronic components 2 are arranged, at least one electronic component 2 is indirectly arranged on the support member 10 inside each of the plurality of cavities 141 of the lattice frame 140. In the resin molding step, the plurality of resin structures 3 is formed by using the lattice frame 140. In the resin molding step, when the plurality of resin structures are molded, the resin structure 3 is molded in each of the plurality of cavities 141 of the lattice frame 140. In the method for manufacturing the electronic component module 1 according to Preferred Embodiment 1, when the plurality of resin structures 3 are molded, the relative positional accuracy between the electronic component 2 and the columnar electrodes 4 held in each of the plurality of resin structures 3 can be improved.

In addition, the method for manufacturing the electronic component module 1 according to Preferred Embodiment 1 further includes a conductive layer removing step and a conductor wiring portion forming step. In the conductive layer removing step, the conductive layer 13 is removed by etching the conductive layer 13 after the resin molding step. In the conductor wiring portion forming step, after the conductive layer removing step, at least the conductor wiring portion 5 connecting the electronic component 2 and the columnar electrode 4 is formed. As a result, in the method for manufacturing the electronic component module 1 according to Preferred Embodiment 1, it is possible to connect the electronic component 2 and the columnar electrode 4 only by the conductor wiring portion 5.

Further, the method for manufacturing the electronic component module 1 according to Preferred Embodiment 1 further includes the conductor frame removing step. In the conductor frame removing step, the conductor frame 14 is removed by etching the conductor frame 14 after the resin molding step and the conductor wiring portion forming step. Accordingly, in the method for manufacturing the electronic component module 1 according to Preferred Embodiment 1, the plurality of resin structures 3 formed in the resin molding step can be separated into the individual resin structures 3 by etching the conductor frame 14. Therefore, as compared with a case where dicing is performed using a blade or a laser, for example, the relative positional accuracy between the outer peripheral surface 33 of the resin structure 3 and each of the columnar electrode 4, the electronic component 2, and the conductor wiring portion 5 can be improved. As a result, in the method for manufacturing the electronic component module 1, it is possible to reduce the size of the resin structure 3 and to reduce the size of the electronic component module 1. Further, in the method for manufacturing the electronic component module 1 according to Preferred Embodiment 1, alignment accuracy in the photolithography in the conductor wiring portion forming step can be improved, and the relative positional accuracy of the conductor wiring portion 5 with respect to the electronic component 2 and the columnar electrode 4 can be improved.

### Modification 1 of Preferred Embodiment 1

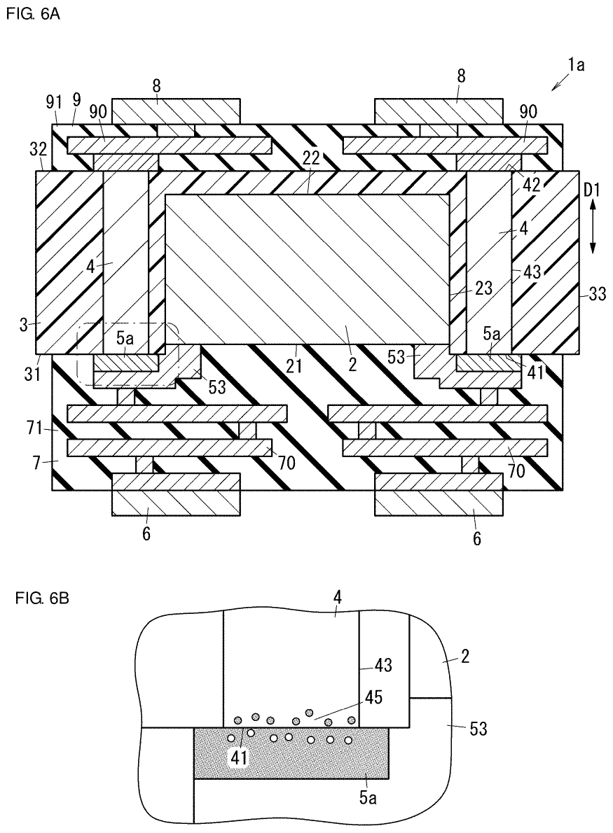

Hereinafter, an electronic component module 1a according to Modification 1 of Preferred Embodiment 1 of the present invention will be described with reference to FIGS. 6A and 6B.

The electronic component module 1a according to Modification 1 of Preferred Embodiment 1 is different from the electronic component module 1 according to Preferred Embodiment 1 in that a conductor wiring portion 5a directly connected to the columnar electrode 4 is provided, instead of the conductor wiring portion 5 directly connected to both of the columnar electrode 4 and the electronic component 2 in the electronic component module 1 according to Preferred Embodiment 1. In the electronic component module 1a according to Modification 1 of Preferred Embodiment 1, elements the same as or similar to those of the electronic component module 1 according to Embodiment 1 are denoted by the same reference numerals, and the description thereof will be omitted.

The electronic component module 1a according to Modification 1 of Preferred Embodiment 1 further includes a wiring portion 53 that electrically connects the conductor wiring portion 5a and the electronic component 2. The wiring portion 53 is directly connected to both of the conductor wiring portion 5a and the electronic component 2. The first terminal electrode 6 is electrically connected to the conductor wiring portion 5a via the wiring portion 70 and the wiring portion 53. A material of the wiring portion 53 is, for example, a metal or an alloy. The material of the wiring portion 53 is, for example, copper.

The method for manufacturing the electronic component module 1a according to Modification 1 of Preferred Embodiment 1 is different from the method for manufacturing the electronic component module 1 according to Preferred Embodiment 1 in that a new eighth step and a new ninth step are included, instead of the eighth step and the ninth step of the method for manufacturing the electronic component module 1 according to Preferred Embodiment 1.

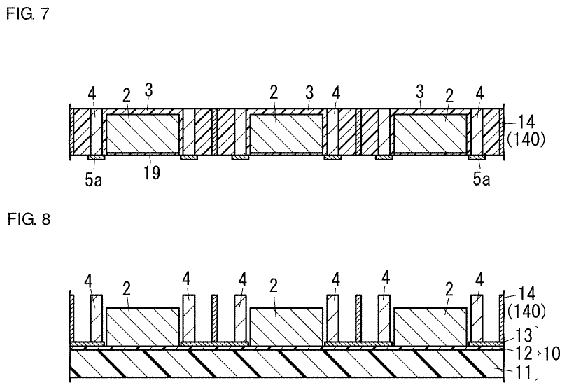

In the eighth step in the method for manufacturing the electronic component module 1a according to Modification 1 of Preferred Embodiment 1, the conductor wiring portion 5a is formed by patterning the conductive layer 13 in the structure (see FIG. 4C) including the plurality of electronic components 2, the plurality of resin structures 3, the plurality of columnar electrodes 4, the conductor frame 14, the conductive layer 13, and the plurality of resin adhesive layers 19 (see FIG. 7). Here, in the new eighth step, for example, the conductor wiring portion 5a is formed by a photolithography technique and an etching technique. In the method for manufacturing the electronic component module 1a according to Modification 1, the new eighth step includes the conductor wiring portion forming step. In addition, in the new ninth step, the plurality of resin adhesive layers 19 are removed from a structure (see FIG. 7) including the plurality of electronic components 2, the plurality of resin structures 3, the plurality of columnar electrodes 4, the conductor frame 14, the plurality of conductor wiring portions 5a, and the plurality of resin adhesive layers 19. In the new eighth step, an element other than the conductor wiring portion 5a may be formed from the conductive layer 13, and for example, the conductor wiring portion 5a and the ground electrode may be formed from the conductive layer 13.

In the method for manufacturing the electronic component module 1a according to Modification 1 of Preferred Embodiment 1, similar to the method for manufacturing the electronic component module 1 according to Preferred Embodiment 1, before a resin molding step, the conductive layer 13 and the columnar electrode 4 are heated so that mutual diffusion occurs between the conductive layer 13 and the columnar electrode 4 in the heat treatment step. As a result, in the method for manufacturing the electronic component module 1a according to Modification 1 of Preferred Embodiment 1, the positional accuracy of the columnar electrodes 4 can be improved in the electronic component module 1a including the columnar electrodes 4, the electronic component 2, and the resin structure 3.

Also, in the method for manufacturing the electronic component module 1a according to Modification 1 of Preferred Embodiment 1, a conductor frame removing step is performed after the conductor wiring portion forming step, and therefore it is possible to improve the alignment accuracy in the photolithography in the conductor wiring portion forming step. As a result, in the method for manufacturing the electronic component module 1a according to Modification 1 of Preferred Embodiment 1, it is possible to improve the relative positional accuracy of the conductor wiring portion 5a with respect to the electronic component 2 and the columnar electrode 4.

The electronic component module 1a according to Modification 1 of Preferred Embodiment 1 includes the electronic component 2, the resin structure 3, the columnar electrode 4, and the conductor wiring portion 5a. The resin structure 3 covers at least a portion of the outer peripheral surface 23 of the electronic component 2 (here, the entirety or substantially the entirety of the outer peripheral surface 23). The columnar electrode 4 passes through the resin structure 3. The conductor wiring portion 5a is connected to the columnar electrode 4. The columnar electrode 4 and the conductor wiring portion 5a are made of different materials from each other. In the electronic component module 1a according to Modification 1 of Preferred Embodiment 1, mutual diffusion occurs between the conductor wiring portion 5a and the columnar electrode 4. Here, a first conductor portion is one of the columnar electrode 4 and the conductor wiring portion 5a and includes, at an end thereof in contact with a second conductor portion that is different from the first conductor portion of the columnar electrode 4 and the conductor wiring portion 5a, a diffusion region 45 (see FIG. 6B) including an element of a material of the second conductor portion.

In the electronic component module 1a according to Modification 1 of Preferred Embodiment 1, the positional accuracy of the columnar electrodes 4 can be improved in the electronic component module 1 including the columnar electrode 4, the electronic component 2, and the resin structure 3. In the electronic component module 1a according to Modification 1 of Preferred Embodiment 1, for example, in a case where the material of the columnar electrode 4 is copper and a material of the conductor wiring portion 5a is a material in which nickel is added to copper, the first conductor portion is the columnar electrode 4 and the second conductor portion is the conductor wiring portion 5a, and the diffusion region 45 in the columnar electrode 4 (first conductor portion) includes nickel as the element of the material of the conductor wiring portion 5a (second conductor portion). Therefore, in the electronic component module 1a according to Modification 1 of Preferred Embodiment 1, the bonding strength between the columnar electrodes 4 and the conductor wiring portion 5a can be increased as compared with a case where the diffusion region 45 is not provided.

### Modification 2 of Preferred Embodiment 1

In the method for manufacturing the electronic component module according to Modification 2 of Preferred Embodiment 1 of the present invention, the conductive layer 13 may be patterned before the heat treatment step in the method for manufacturing the electronic component module 1 according to Preferred Embodiment 1, as illustrated in FIG. 8. When patterning the conductive layer 13, before the above-described heat treatment step, the conductive layer 13 is patterned so as to overlap each columnar electrodes 4 and the conductor frame 14 and to overlap a periphery of each columnar electrode 4 and a periphery of the conductor frame 14 in a plan view from a thickness direction of the support body 11. In other words, the patterned conductive layer 13 overlaps all of the columnar electrodes 4 and the conductor frame 14 in a plan view from the thickness direction of the support body 11, and is larger than each columnar electrode 4 and the conductor frame 14. In the step of patterning the conductive layer 13, the conductive layer 13 is patterned by, for example, a photolithography technique and an etching technique.

In the method for manufacturing the electronic component module according to Modification 2 of Preferred Embodiment 1, when the electronic component 2 is arranged on the support member 10, the electronic component 2 faces the bonding layer 12 without forming the resin adhesive layer 19 (see FIG. 2C), and the electronic component 2 is arranged on the bonding layer 12. That is, in the method for manufacturing the electronic component module according to Modification 2 of Preferred Embodiment 1, in the component arrangement step, the electronic component 2 is directly arranged on the support member 10. This makes it possible to omit the process of forming the resin adhesive layer 19.

The method for manufacturing the electronic component module according to Modification 2 of Preferred Embodiment 1 includes the heat treatment step similar to that of the method for manufacturing the electronic component module 1 according to Preferred Embodiment 1. As a result, in the method for manufacturing the electronic component module according to Modification 2 of Preferred Embodiment 1, it is possible to improve the positional accuracy of the columnar electrode 4 in the electronic component module including the columnar electrode 4, the electronic component 2, and the resin structure 3.

In the electronic component module 1 according to Preferred Embodiment 1, the second main surface 32 of the resin structure 3 is planar, and a distance from the second main surface 32 of the resin structure 3 to the first main surface 21 of the electronic component 2 is shorter than a distance from the second main surface 32 of the resin structure 3 to the first main surface 31 of the resin structure 3. As a result, the resin structure 3 covers the entirety or substantially the entirety of the outer peripheral surface 23 of the electronic component 2 and the entirety or substantially the entirety of the second main surface 22 of the electronic component 2.

On the other hand, in the electronic component module manufactured by the method for manufacturing the electronic component module according to Modification 2 of Preferred Embodiment 1, the shortest distance from the second main surface 32 of the resin structure 3 to the first main surface 21 of the electronic component 2 is the same or substantially the same as the shortest distance from the second main surface 32 to the first main surface 31 of the resin structure 3.

In the method for manufacturing the electronic component module according to Modification 2 of Preferred Embodiment 1, similar to the method for manufacturing the electronic component module 1 according to Preferred Embodiment 1, before the resin molding step, the conductive layer 13 and the columnar electrode 4 are heated so that mutual diffusion occurs between the conductive layer 13 and the columnar electrode 4 in the heat treatment step. As a result, in the method for manufacturing the electronic component module according to Modification 2 of Preferred Embodiment 1, it is possible to improve the positional accuracy of the columnar electrode 4 in the electronic component module including the columnar electrode 4, the electronic component 2, and the resin structure 3.

### Preferred Embodiment 2

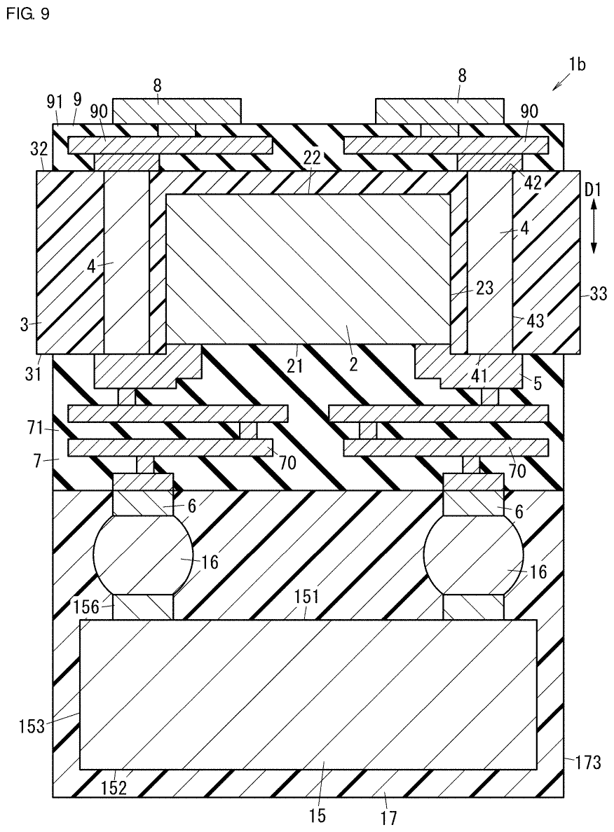

Hereinafter, an electronic component module 1b according to Preferred Embodiment 2 of the present invention will be described with reference to FIG. 9.

The electronic component module 1b according to Preferred Embodiment 2 is different from the electronic component module 1 according to Preferred Embodiment 1 in that a second electronic component 15 that is different from the electronic component 2 (hereinafter, also referred to as a first electronic component 2) is further provided. In the electronic component module 1b according to Preferred Embodiment 2, elements the same as or similar to those of the electronic component module 1 according to Preferred Embodiment 1 are denoted by the same reference numerals, and the description thereof will be omitted.

The second electronic component 15 partially overlaps the resin structure 3 in a plan view from the thickness direction D1 of the resin structure 3. Here, the second electronic component 15 also overlaps the first electronic component 2 in the plan view from the thickness direction D1 of the resin structure 3.

The second electronic component 15 is a chip electronic component. The second electronic component 15 includes a first main surface 151 and a second main surface 152 on opposite sides to each other in the thickness direction of the second electronic component 15. The second main surface 152 faces the first main surface 151. Further, the second electronic component 15 includes an outer peripheral surface 153. An outer peripheral shape of the second electronic component 15 when the second electronic component 15 is viewed from the thickness direction thereof is a rectangular or substantially rectangular shape, but is not limited thereto, and may be, for example, a square or substantially square shape.

The second electronic component 15 is, for example, an integrated circuit (IC). The second electronic component 15 is not limited to the IC, and may be, for example, an inductor, a capacitor, a switch, a power amplifier, or a low-noise amplifier. The second electronic component 15 includes a plurality of terminal electrodes 156 on the side of the first main surface 151 of the first main surface 151 and the second main surface 152. The electronic component module 1b further includes a plurality of bumps 16 that electrically and mechanically connect the plurality of first terminal electrodes 6 and the plurality of terminal electrodes 156 of the second electronic component 15. Each bump 16 is, for example, a solder bump. Each bump 16 is not limited to the solder bump, and may be, for example, a gold bump.

Further, the electronic component module 1b according to Preferred Embodiment 2 further includes a sealing layer 17 that seals the second electronic component 15. The sealing layer 17 covers at least the second main surface 152 and the outer peripheral surface 153 of the second electronic component 15. Here, the sealing layer 17 also covers a portion other than the terminal electrode 156 on the first main surface 151 of the second electronic component 15. As a material of the sealing layer 17, for example, a polyimide resin, benzocyclobutene, polybenzoxazole, a phenol resin, or a silicone resin may be used. The material of the sealing layer 17 may be the same as or different from that of the resin structure 3. Further, the sealing layer 17 only needs to include at least resin, and may or may not include, for example, a filler, in addition to the resin.

An arithmetic average roughness Ra of the entire outer peripheral surface 33 of the resin structure 3 is smaller than an arithmetic average roughness Ra of the entire outer peripheral surface 173 of the sealing layer 17. The arithmetic average roughness Ra is defined, for example, by JIS B 0601-2001 (ISO 4287-1997). The arithmetic average roughness Ra can be measured by, for example, a three dimensional shape measuring device, such as an Atomic Force Microscope (AFM).

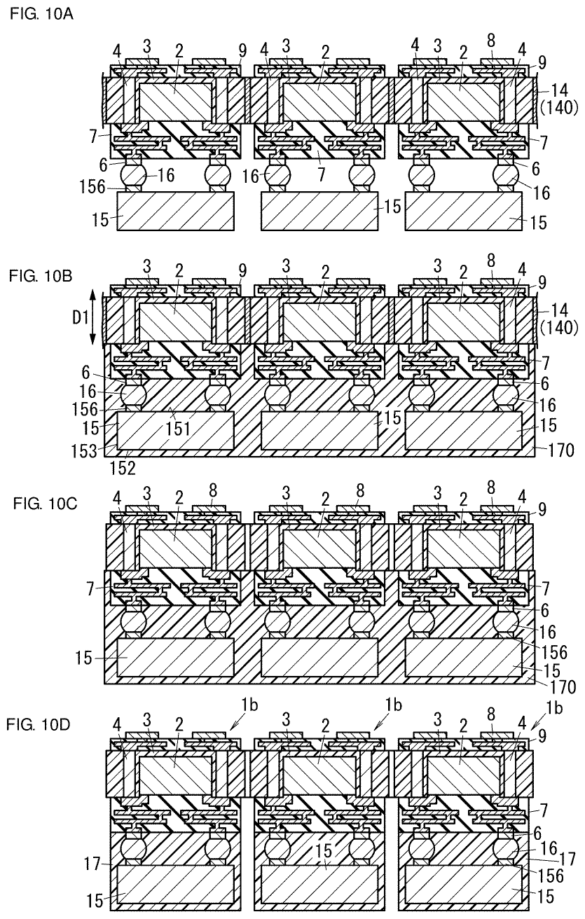

Hereinafter, an example of the method for manufacturing the electronic component module 1b according to Preferred Embodiment 2 will be described with reference to FIGS. 10A to 10D. Note that steps the same as or similar to those in the method for manufacturing the electronic component module 1 according to Preferred Embodiment 1 will be omitted as appropriate.

In the method for manufacturing the electronic component module 1b, after the twelfth step described in Preferred Embodiment 1, the plurality of electronic component modules 1b are obtained by performing the following thirteenth to sixteenth steps.

In the thirteenth step, as illustrated in FIG. 10A, the plurality of terminal electrodes 156 of the second electronic component 15 and the plurality of first terminal electrodes 6 on the first wiring structure portion 7 are electrically and mechanically connected via the bump 16. In the method for manufacturing the electronic component module 1b according to Preferred Embodiment 2, the thirteenth step includes a second electronic component arrangement step in which the plurality of second electronic components 15 different from the plurality of first electronic components 2 are arranged so as to partially overlap the resin structure 3 in the thickness direction D1 of the corresponding resin structure 3 among the plurality of resin structures 3.

In the fourteenth step, as illustrated in FIG. 10B, a sealing resin layer 170 that defines and functions as a source of the plurality of sealing layers 17 is formed. The sealing resin layer 170 overlaps the plurality of resin structures 3 and the conductor frame 14 as a lattice frame in a plan view from the thickness direction D1 of the resin structure 3, and covers the plurality of second electronic components 15. As a material of the sealing resin layer 170, for example, the polyimide resin, benzocyclobutene, polybenzoxazole, the phenol resin, or the silicone resin may be used. In the method for manufacturing the electronic component module 1b according to Preferred Embodiment 2, the fourteenth step includes a sealing step of forming the sealing resin layer 170 that defines and functions as a source of the plurality of sealing layers 17.

In the fifteenth step, as illustrated in FIG. 10C, the conductor frame 14 (lattice frame 140) is removed. Here, in the fifteenth step, the conductor frame 14 is removed by etching. In the fifteenth step, the conductor frame 14 is removed by wet etching. As the etchant for wet etching the conductor frame 14, for example, a nitric acid-based solution, an iron chloride-based solution, or a sulfuric acid-based solution may be used. The etchant used in the fifteenth step is preferably an etchant having large etching selectivity (the etching rate of the conductor frame 14/the etching rate of the resin structure 3), and more preferably an etchant in which the resin structure 3 is not etched, from the viewpoint of selectively etching the conductor frame 14 with respect to the resin structure 3. In the method for manufacturing the electronic component module 1b according to Preferred Embodiment 2, the fifteenth step includes a conductor frame removing step of removing the conductor frame 14 by etching the conductor frame 14 after a resin molding step.

In the sixteenth step, as illustrated in FIG. 10D, the sealing resin layer 170 is diced at a position (that is, a position corresponding to the lattice frame 140) that overlaps a lattice-shaped groove formed by the removal of the lattice frame 140, thus dividing the sealing resin layer 170 into individual sealing layers 17. In the sixteenth step, the dicing is performed using a dicing blade, but is not limited thereto, and for example, dicing may be performed by using a laser. In the method for manufacturing the electronic component module 1b according to Preferred Embodiment 2, the sixteenth step includes a dicing step of dicing the sealing resin layer 170 at a position overlapping with the lattice frame 140. In the method for manufacturing the electronic component module 1b according to Preferred Embodiment 2, a separation step including the fifteenth step and the sixteenth step is performed on an assembly including the plurality of resin structures 3, the plurality of first electronic components 2, the plurality of second electronic components 15, and the sealing resin layer 170, thus obtaining the plurality of electronic component modules 1b.

The method for manufacturing the electronic component module 1b according to Preferred Embodiment 2 includes a heat treatment step the same as or similar to that of the method for manufacturing the electronic component module 1 according to Preferred Embodiment 1. As a result, in the method for manufacturing the electronic component module 1b according to Preferred Embodiment 2, it is possible to improve positional accuracy of the columnar electrode 4 in the electronic component module 1b including the columnar electrode 4, the electronic component 2, and the resin structure 3.

The method for manufacturing the electronic component module 1b according to Preferred Embodiment 2 further includes, in addition to the steps (the first to twelfth steps) in the method for manufacturing the electronic component module 1 according to Preferred Embodiment 1, the second electronic component arrangement step, the sealing step, and the dicing step. In the second electronic component arrangement step, the plurality of second electronic components 15 different from the plurality of first electronic components 2 are arranged so as to partially overlap the resin structure 3 in the thickness direction D1 of the corresponding resin structure 3 among the plurality of resin structures 3, after the conductor wiring portion forming step. In the sealing step, the resin layer overlapping the plurality of resin structures 3 and the conductor frame 14 as a lattice frame in a plan view from the thickness direction D1 of the resin structure 3, that is, the sealing resin layer 170 that covers the plurality of second electronic components 15 is formed. In the dicing step, the sealing resin layer 170 is diced at a position overlapping (the lattice-shaped groove formed by the removal of) the conductor frame 14 as a lattice frame.

In the method for manufacturing the electronic component module 1b according to Preferred Embodiment 2, a surface roughness of the entire outer peripheral surface 33 of the resin structure 3 in the electronic component module 1b is substantially determined by a surface roughness of the outer peripheral surface 33 exposed by performing the conductor frame removing step, and a surface roughness of the entire outer peripheral surface 173 of the sealing layer 17 is substantially determined by a surface roughness of the outer peripheral surface 173 of the sealing layer 17 formed by performing the dicing step. As a result, in the method for manufacturing the electronic component module 1b according to Preferred Embodiment 2, the arithmetic average roughness Ra of the entire outer peripheral surface 33 of the resin structure 3 in the electronic component module 1b is smaller than the arithmetic average roughness Ra of the entire outer peripheral surface 173 of the sealing layer 17 in the electronic component module 1b.

### Modification 1 of Preferred Embodiment 2

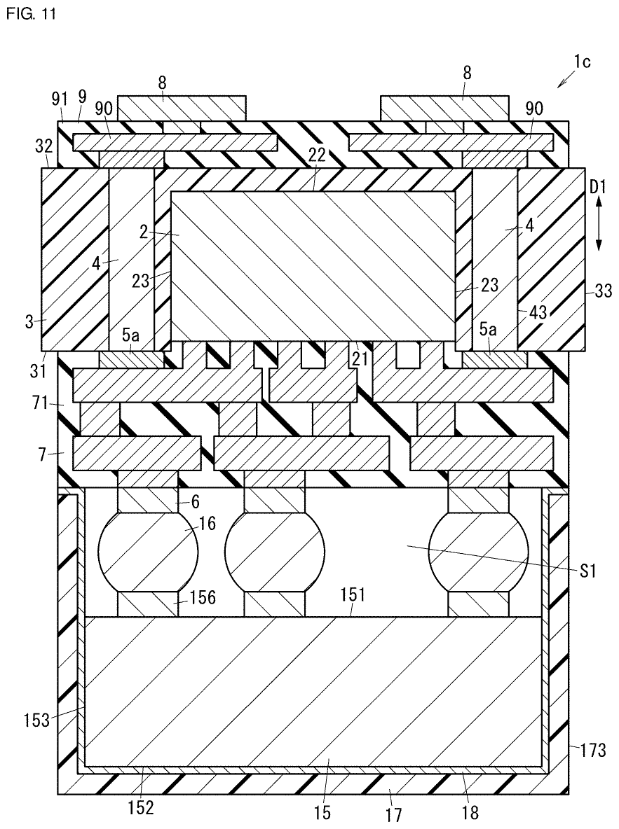

Hereinafter, an electronic component module 1c according to Modification 1 of Preferred Embodiment 2 of the present invention will be described with reference to FIG. 11.

The electronic component module 1c according to Modification 1 of Preferred Embodiment 2 is different from the electronic component module 1b according to Preferred Embodiment in that an acoustic wave element is provided as the second electronic component 15. In the electronic component module 1c according to Modification 1 of Preferred Embodiment 2, elements the same as or similar to those of the electronic component module 1b according to Preferred Embodiment 2 are denoted by the same reference numerals, and the description thereof will be omitted.

The acoustic wave element defining and functioning as the second electronic component 15 is, for example, a high-frequency device, such as a Surface Acoustic Wave (SAW) filter. The high-frequency device that defines the acoustic wave element is not limited to the SAW filter, and may be, for example, a bulk acoustic wave (BAW) filter. Further, the high-frequency device may be a duplexer using the SAW filter. A semiconductor chip as the first electronic component 2 is, for example, a power amplifier that amplifies a signal having passed through the SAW filter as the second electronic component 15.

In the case of the SAW filter, the second electronic component 15 includes, for example, a piezoelectric substrate including a first main surface and a second main surface on opposite sides to each other in the thickness direction, and a plurality of interdigital transducer (IDT) electrodes formed on the first main surface of the piezoelectric substrate. The first main surface and the second main surface of the piezoelectric substrate face each other. The piezoelectric substrate is, for example, a lithium niobate (LiNbO₃) substrate, but is not limited thereto, and may be, for example, a lithium tantalate (LiTaO₃) substrate or a quartz substrate. In the SAW filter, a plurality of surface acoustic wave resonators including each of the plurality of IDT electrodes are electrically connected to define a filter.

In the electronic component module 1c according to Modification 1 of Preferred Embodiment 2, the second main surface 152 and the outer peripheral surface 153 of the second electronic component 15 are covered with the sealing layer 17 via a shield layer 18. Note that the shield layer 18 is not a necessary element. Further, the electronic component module 1c according to Modification 1 of Preferred Embodiment 2 includes the conductor wiring portion 5a, which is similar to the electronic component module 1a according to Modification 1 of Preferred Embodiment 1, instead of the conductor wiring portion 5 in the electronic component module 1b according to Preferred Embodiment 2.

In the electronic component module 1c according to Modification 1 of Preferred Embodiment 2, a space S1 surrounded by the second electronic component 15, the shield layer 18, and the first wiring structure portion 7 is provided. In the piezoelectric substrate in the second electronic component 15, the first main surface of the first main surface and the second main surface is located on the space S1 side. Note that, in the electronic component module 1c according to Modification 1 of Preferred Embodiment 2, in a case where the shield layer 18 is not provided, the space S1 surrounded by the second electronic component 15, the sealing layer 17, and the first wiring structure portion 7 is provided.

The method for manufacturing the electronic component module 1c according to Modification 1 of Preferred Embodiment 2 is the same or substantially the same as the method for manufacturing the electronic component module 1b of Preferred Embodiment 2, and differs therefrom in that the shield layer forming step of forming a shielding layer 18 is provided, and that the space S1 is formed when the sealing resin layer 170 is formed in the sealing step.

The method for manufacturing the electronic component module 1c according to Modification 1 of Preferred Embodiment 2 includes a heat treatment step the same as or similar to that of the electronic component module 1 according to Preferred Embodiment 1. As a result, in the method for manufacturing the electronic component module 1c according to Modification 1 of Preferred Embodiment 2, the positional accuracy of the columnar electrodes 4 can be improved in the electronic component module 1c including the columnar electrodes 4, the electronic component 2, and the resin structure 3.

### Modification 2 of Preferred Embodiment 2

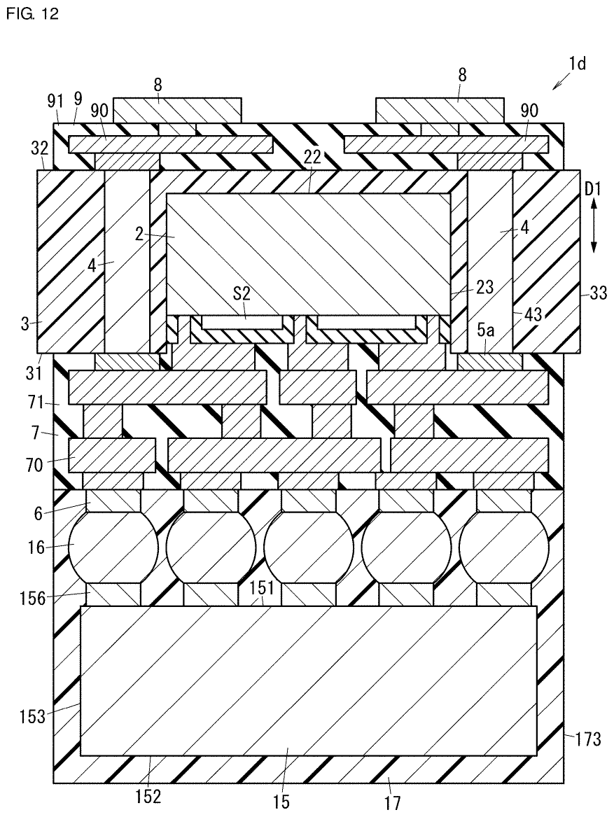

Hereinafter, an electronic component module 1d according to Modification 2 of Preferred Embodiment 2 of the present invention will be described with reference to FIG. 12.

The electronic component module 1d according to Modification 2 of Preferred Embodiment 2 is different from the electronic component module 1b according to Preferred Embodiment in that an acoustic wave element is provided as the first electronic component 2. In the electronic component module 1d according to Modification 2 of Preferred Embodiment 2, elements the same as or similar to those of the electronic component module 1b according to Preferred Embodiment 2 are denoted by the same reference numerals, and the description thereof will be omitted.

The acoustic wave element as the first electronic component 2 is, for example, a high-frequency device, such as a SAW filter. The high-frequency device that defines the acoustic wave element is not limited to the SAW filter, and may be, for example, a BAW filter. Further, the high-frequency device may be, for example, a duplexer using the SAW filter. A semiconductor chip as the second electronic component 15 is, for example, a power amplifier that amplifies a signal having passed through the SAW filter as the first electronic component 2. The semiconductor chip as the second electronic component 15 is not limited to the power amplifier, and may be, for example, a low-noise amplifier that amplifies a high-frequency signal from an antenna and outputs the amplified high-frequency signal to the SAW filter as the first electronic component 2.

In the case of the SAW filter, the first electronic component 2 includes, for example, a piezoelectric substrate including a first main surface and a second main surface on opposite sides to each other in the thickness direction, and a plurality of IDT electrodes on the first main surface of the piezoelectric substrate. The piezoelectric substrate is, for example, a lithium niobate substrate, but is not limited thereto, and may be the lithium tantalate substrate or the quartz substrate, for example. In the SAW filter, a plurality of surface acoustic wave resonators including each of the plurality of IDT electrodes ARE electrically connected to define a filter.

In the electronic component module 1d according to Modification 2 of Preferred Embodiment 2, the first electronic component 2 includes a space S2 to expose the plurality of IDT electrodes. Further, the electronic component module 1d according to Modification 2 of Preferred Embodiment 2 includes the conductor wiring portion 5a, which is the same as or similar to the electronic component module 1a according to Modification 1 of Preferred Embodiment 1, instead of the conductor wiring portion 5 in the electronic component module 1b according to Preferred Embodiment 2.

The method for manufacturing the electronic component module 1d according to Modification 2 of Preferred Embodiment 2 is the same or substantially the same as the method for manufacturing the electronic component module 1b according to Preferred Embodiment 2.

The method for manufacturing the electronic component module 1d according to Modification 2 of Preferred Embodiment 2 includes the heat treatment step the same as or similar to that of the electronic component module 1 according to Preferred Embodiment 1. As a result, in the method for manufacturing the electronic component module 1d according to Modification 2 of Preferred Embodiment 2, the positional accuracy of the columnar electrodes 4 can be improved in the electronic component module 1d including the columnar electrodes 4, the electronic component 2, and the resin structure 3.

Preferred Embodiments 1 to 2 and the like described above are only examples of preferred embodiments of the present invention. As long as the advantageous effects of the present invention can be achieved, Preferred Embodiments 1 to 2 and the like can be variously changed according to the design and the like.

For example, in the support member preparation step, the conductive layer 13 is indirectly provided on the first main surface 111 of the support body 11, but is not limited thereto, and may be directly provided.

In addition, in the resin molding step, the resin structure 3 that covers the outer peripheral surface 43 of the columnar electrode 4 and the entirety or substantially the entirety of the outer peripheral surface 23 of the electronic component 2 is molded on the conductive layer 13, but is not limited thereto, and the resin structure 3 may be molded so as to cover the outer peripheral surface 43 of the columnar electrode 4 and at least a portion of the outer peripheral surface 23 of the electronic component 2 on the conductive layer 13. In addition, in the resin molding step, the resin structure 3 is molded so as to also cover the second main surface 22 of the electronic component 2. However, it is not necessary to cover the second main surface 22 of the electronic component 2.

A method for manufacturing an electronic component module (1; 1a; 1b; 1c; 1d) according to a preferred embodiment of the present invention includes a support member preparation step, an electrode forming step, a component arrangement step, and a resin molding step. In the support member preparation step, a support member (10) including a support body (11) and a conductive layer (13) is prepared. The support body (11) includes a first main surface (111) and a second main surface (112). The conductive layer (13) is provided directly or indirectly on the first main surface (111) of the support body (11). In the electrode forming step, a columnar electrode (4) is formed on the conductive layer (13). In the component arrangement step, an electronic component (2) is arranged directly or indirectly on the support member (10) on a side of the first main surface (111) of the support body (11). In the resin molding step, a resin structure (3) that covers an outer peripheral surface (43) of the columnar electrode (4) and at least a portion of an outer peripheral surface (23) of the electronic component (2) is molded on the conductive layer (13). In the electrode forming step, the columnar electrode (4) is formed of a material different from a material of the conductive layer (13). The method for manufacturing the electronic component module (1; 1a; 1b; 1c; 1d) further includes a heat treatment step. In the heat treatment step, the conductive layer (13) and the columnar electrode (4) are heated so that mutual diffusion occurs between the conductive layer (13) and the columnar electrode (4) between the electrode forming step and the resin molding step.

In a method for manufacturing an electronic component module (1; 1a; 1b; 1c; 1d) according to a preferred embodiment of the present invention, it is possible to improve positional accuracy of the columnar electrodes (4) in the electronic component module (1; 1a; 1b; 1c; 1d) including the columnar electrode (4), the electronic component (2), and the resin structure (3).

In a method for manufacturing an electronic component module (1; 1a; 1b; 1c; 1d) according to a preferred embodiment of the present invention, the columnar electrode (4) is formed by electrolytic plating in the electrode forming step.

In a method for manufacturing an electronic component module (1; 1a; 1b; 1c; 1d) according to a preferred embodiment of the present invention, the columnar electrode (4) can be easily formed.

A method for manufacturing an electronic component module (1; 1a; 1b; 1c; 1d) according to a preferred embodiment of the present invention includes a conductor frame forming step. In the conductor frame forming step, before the resin molding step, a conductor frame (14) including a cavity (141) that defines a molding planned region of the resin structure (3) is formed on the conductive layer (13). In the heat treatment step, the conductive layer (13) and the conductor frame (14) are heated so that mutual diffusion occurs between the conductive layer (13) and the conductor frame (14).

In a method for manufacturing an electronic component module (1; 1a; 1b; 1c; 1d) according to a preferred embodiment of the present invention, the conductive layer (13) and the conductor frame (14) are heated so that mutual diffusion occurs between the conductive layer (13) and the conductor frame (14), and thus it is possible to increase bonding strength between the conductive layer (13) and the conductor frame (14). Accordingly, in the electronic component module (1; 1a; 1b; 1c; 1d) according to the present preferred embodiment, when the resin structure (3) is formed in the resin molding step, in a case where the columnar electrode (4) and the conductive layer (13) are applied with force due to the flow of resin and the contraction of resin when the resin is cured, the columnar electrode (4) is less likely to be peeled off from the conductive layer (13). Therefore, relative positional accuracy between the electronic component (2) and the columnar electrodes (4) can be improved in the electronic component module (1; 1a; 1b; 1c; 1d) including the columnar electrode (4), the electronic component (2), and the resin structure (3).

In a method for manufacturing an electronic component module (1; 1a; 1b; 1c; 1d) according to a preferred embodiment of the present invention, the electrode forming step and the conductor frame forming step are the same step.

In a method for manufacturing an electronic component module (1; 1a; 1b; 1c; 1d) according to a preferred embodiment of the present invention, the columnar electrode (4) and the conductor frame (14) can be formed by the same step, and the relative positional accuracy between the columnar electrode (4) and the conductor frame (14) can be improved.

In a method for manufacturing an electronic component module (1; 1a; 1b; 1c; 1d) according to a preferred embodiment of the present invention, a lattice frame (140) including a plurality of cavities (141) as the conductor frame (14) is formed on the conductive layer (13) in the conductor frame forming step. In the electrode forming step, a plurality of columnar electrodes (4) is formed with respect to the conductive layer (13). In the electrode forming step, when forming the plurality of columnar electrodes (4), at least one columnar electrode (4) is formed on the conductive layer (13) inside each of the plurality of cavities (141) of the lattice frame (140). In the component arrangement step, a plurality of electronic components (2) are arranged in the conductive layer (13). In the component arrangement step, when arranging the plurality of electronic components (2), at least one electronic component (2) is arranged on the conductive layer (13) inside each of the plurality of cavities (141) of the lattice frame (140). In the resin molding step, a plurality of resin structures (3) are formed by using the lattice frame (140). In the resin molding step, when the plurality of resin structures (3) is molded, the resin structure (3) is molded in each of the plurality of cavities (141) of the lattice frame (140).

In a method for manufacturing an electronic component module (1; 1a; 1b; 1c; 1d) according to a preferred embodiment of the present invention, when the plurality of resin structures (3) is molded, the relative positional accuracy between the electronic component (2) and the columnar electrodes (4) held in each of the plurality of resin structures (3) can be improved.

A method for manufacturing an electronic component module (1; 1b; 1c; 1d) according to a preferred embodiment of the present invention further includes a conductive layer removing step and a conductor wiring portion forming step. In the conductive layer removing step, the conductive layer (13) is removed by etching the conductive layer (13) after the resin molding step. In the conductor wiring portion forming step, a conductor wiring portion (5) that connects the electronic component (2) and the columnar electrode (4) is formed after the conductive layer removing step.

In a method for manufacturing an electronic component module (1; 1b; 1c; 1d) according to a preferred embodiment of the present invention, it is possible to connect the electronic component (2) and the columnar electrode (4) only by the conductor wiring portion (5).

A method for manufacturing an electronic component module (1a) according to a preferred embodiment of the present invention further includes a conductor wiring portion forming step. In the conductor wiring portion forming step, the conductive layer (13) is patterned after the resin molding step, so that the conductor wiring portion (5a) connected to the columnar electrode (4) is formed from the conductive layer (13).

In a method for manufacturing an electronic component module (1a) according to a preferred embodiment of the present invention, it is possible to improve the relative positional accuracy of the conductor wiring portion (5a) with respect to the electronic component (2) and the columnar electrode (4).

A method for manufacturing an electronic component module (1; 1a; 1b; 1c; 1d) according to a preferred embodiment of the present invention further includes a conductor frame removing step. In the conductor frame removing step, the conductor frame (14) is removed by etching the conductor frame (14) after the conductor wiring portion forming step.

In a method for manufacturing an electronic component module (1; 1a; 1b; 1c; 1d) according to a preferred embodiment of the present invention, it is possible to improve the relative positional accuracy of the conductor wiring portion (5; 5a) formed with respect to the electronic component (2) and the columnar electrode (4) in the conductor wiring portion forming step.

A method for manufacturing an electronic component module (1; 1a; 1b; 1c; 1d) according to a preferred embodiment of the present invention further includes a second electronic component arrangement step, a sealing step, and a dicing step. In the second electronic component arrangement step, between the conductor wiring portion forming step and the conductor frame removing step, a plurality of second electronic components (15) different from the plurality of first electronic components as the plurality of electronic components (2) are arranged so as to at least partially overlap the corresponding resin structure (3) among the plurality of resin structures (3) in the thickness direction (D1) of the resin structure (3). In the sealing step, after the second electronic component arrangement step, a resin layer that covers the plurality of second electronic components (15) so as to overlap the plurality of resin structures (3) and the lattice frame (140) in a plan view from the thickness direction (D1), that is, the sealing resin layer (170) that defines and functions as a source of the plurality of sealing layers (17) is formed. In the dicing step, the sealing resin layer (170) is diced at a position overlapping the lattice frame (140), thereby forming a plurality of sealing layers (17).

An electronic component module (1a) according to a preferred embodiment of the present invention includes the electronic component (2), the resin structure (3), the columnar electrode (4), and the conductor wiring portion (5a). The resin structure (3) covers at least a portion of the outer peripheral surface (23) of the electronic component (2). The columnar electrode (4) passes through the resin structure (3). The conductor wiring portion (5a) is connected to the columnar electrode (4). The columnar electrodes (4) and the conductor wiring portions (5a) are made of different materials from each other. In the electronic component module (1a), mutual diffusion occurs between the conductor wiring portion (5a) and the columnar electrode (4).

In an electronic component module (1a) according to a preferred embodiment of the present invention, it is possible to improve the positional accuracy of the columnar electrode (4) in the electronic component module (1a) including the columnar electrode (4), the electronic component (2), and the resin structure (3).

An electronic component module (1) according to a preferred embodiment of the present invention includes the electronic component (2), the resin structure (3), the columnar electrode (4), and the conductor wiring portion (5). The resin structure (3) covers at least a portion of the outer peripheral surface (23) of the electronic component (2). The columnar electrode (4) passes through the resin structure (3). The conductor wiring portion (5) is connected to one end (410) of the columnar electrode (4). The columnar electrodes (4) and the conductor wiring portions (5) are made of different materials from each other. In the electronic component module (1), the one end (410) of the columnar electrode (4) includes a diffusion region (45) made of a material different from the material of the columnar electrode (4).

In an electronic component module (1) according to a preferred embodiment of the present invention, it is possible to improve the positional accuracy of the columnar electrodes (4) in the electronic component module (1) including the columnar electrode (4), the electronic component (2), and the resin structure (3).

An electronic component module (1; 1a) according to a preferred embodiment of the present invention further includes the second electronic component (15) that is different from the first electronic component as the electronic component (2) and partially overlaps the resin structure (3) in the thickness direction (D1) of the resin structure (3), and the sealing layer (17) that seals the second electronic component (15). An arithmetic average roughness Ra of the entire outer peripheral surface (33) of the resin structure (3) is smaller than an arithmetic average roughness Ra of the entire outer peripheral surface (173) of the sealing layer (17).

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A method for manufacturing an electronic component module, the method comprising:
a support member preparation step of preparing a support member including a support body including a first main surface and a second main surface, and a conductive layer provided directly or indirectly on the first main surface of the support body;
an electrode forming step of forming a columnar electrode on the conductive layer;
a component arrangement step of directly or indirectly arranging an electronic component on the support member on a side of the first main surface of the support body; and
a resin molding step of molding a resin structure that covers an outer peripheral surface of the columnar electrode and at least a portion of an outer peripheral surface of the electronic component on the conductive layer; wherein
in the electrode forming step, the columnar electrode is made of a material different from a material of the conductive layer; and
a heat treatment step of heating the conductive layer and the columnar electrode is included so that mutual diffusion occurs between the conductive layer and the columnar electrode between the electrode forming step and the resin molding step.

2. The method for manufacturing the electronic component module according to claim 1, wherein in the electrode forming step, the columnar electrode is formed by electrolytic plating.

3. The method for manufacturing the electronic component module according to claim 1, wherein
before the resin molding step, a conductor frame forming step of forming a conductor frame including a cavity that defines a molding planned region of the resin structure on the conductive layer is included; and
in the heat treatment step, the conductive layer and the conductor frame are heated so that mutual diffusion occurs between the conductive layer and the conductor frame.

4. The method for manufacturing the electronic component module according to claim 3, wherein the electrode forming step and the conductor frame forming step are a single step.

5. The method for manufacturing the electronic component module according to claim 3, wherein
in the conductor frame forming step, a lattice frame defining the conductor frame and including a plurality of the cavities is formed on the conductive layer;
in the electrode forming step, a plurality of the columnar electrodes are formed;
when forming the plurality of columnar electrodes, at least one columnar electrode is formed on the conductive layer inside each of the plurality of cavities of the lattice frame;
in the component arrangement step, a plurality of the electronic components are arranged with respect to the support member;
when the plurality of electronic components are arranged, at least one electronic component is directly or indirectly arranged on the support member inside each of the plurality of cavities of the lattice frame;
in the resin molding step, a plurality of the resin structures are molded using the lattice frame; and
when the plurality of resin structures are molded, a resin structure is molded in each of the plurality of cavities of the lattice frame.

6. The method for manufacturing the electronic component module according to claim 5, further comprising:
a conductive layer removing step of removing the conductive layer by etching the conductive layer after the resin molding step; and
a conductor wiring portion forming step of forming a conductor wiring portion that connects the electronic component and the columnar electrode after the conductive layer removing step.

7. The method for manufacturing the electronic component module according to claim 5, further comprising a conductive wiring portion forming step of forming a conductor wiring portion connected to the columnar electrode from the conductive layer by patterning the conductive layer after the resin molding step.

8. The method for manufacturing the electronic component module according to claim 6, further comprising a conductor frame removing step of removing the conductor frame by etching the conductor frame after the conductor wiring portion forming step.

9. The method for manufacturing the electronic component module according to claim 8, further comprising:
a second electronic component arrangement step of arranging a plurality of second electronic components different from the plurality of first electronic components so as to at least partially overlap a corresponding resin structure among the plurality of resin structures in a thickness direction of the resin structure, between the conductor wiring portion forming step and the conductor frame removing step;
a sealing step of forming a resin layer that covers the plurality of second electronic components so as to overlap the plurality of resin structures and the lattice frame in a plan view from the thickness direction, the resin layer being a source of a plurality of sealing layers, after the second electronic component arrangement step; and
a dicing step of forming the plurality of sealing layers by dicing the resin layer at a position overlapping the lattice frame.

10. An electronic component module comprising:
an electronic component;
a resin structure covering at least a portion of an outer peripheral surface of the electronic component;
a columnar electrode passing through the resin structure; and
a conductor wiring portion connected to the columnar electrode; wherein
the columnar electrode and the conductor wiring portion are made of different materials from each other; and
a mutual diffusion portion is provided between the conductor wiring portion and the columnar electrode.

11. An electronic component module comprising:
an electronic component;
a resin structure covering at least a portion of an outer peripheral surface of the electronic component;
a columnar electrode passing through the resin structure; and
a conductor wiring portion connected to one end of the columnar electrode; wherein
the columnar electrode and the conductor wiring portion are made of different materials from each other; and
the one end of the columnar electrode includes a diffusion region made of a material different from a material of the columnar electrode.

12. The electronic component module according to claim 10, further comprising:
a second electronic component different from the electronic component at least partially overlapping the resin structure in a thickness direction of the resin structure; and
a sealing layer sealing the second electronic component; wherein
an arithmetic average roughness Ra of an entire outer peripheral surface of the resin structure is smaller than an arithmetic average roughness Ra of an entire outer peripheral surface of the sealing layer.

13. The electronic component module according to claim 11, further comprising:
a second electronic component different from the electronic component at least partially overlapping the resin structure in a thickness direction of the resin structure; and
a sealing layer sealing the second electronic component; wherein
an arithmetic average roughness Ra of an entire outer peripheral surface of the resin structure is smaller than an arithmetic average roughness Ra of an entire outer peripheral surface of the sealing layer.

14. The electronic component module according to claim 10, wherein a plurality of the columnar electrodes pass through the resin structure.

15. The electronic component module according to claim 11, wherein a plurality of the columnar electrodes pass through the resin structure.

16. The electronic component module according to claim 10, wherein the resin structure covers an entirety or substantially an entirety of the outer peripheral surface of the electronic component.

17. The electronic component module according to claim 11, wherein the resin structure covers an entirety or substantially an entirety of the outer peripheral surface of the electronic component.

18. The electronic component module according to claim 15, wherein a plurality of the conductor wiring portions are respectively connected to the plurality of columnar electrodes.

19. The electronic component module according to claim 16, wherein a plurality of the conductor wiring portions are respectively connected to the one ends of the plurality of columnar electrodes.
